(19) United States
(12) Patent Application Publication
(10) Pub. No.: US 2004/0159857 A1
(43) Pub. Date: Aug. 19, 2004

(54) Semiconductor device having vertical transistor

(75) Inventors: Katsuyuki Horita, Tokyo (JP); Takashi Kuroi, Tokyo (JP); Masashi Kitazawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/689,059

(22) Filed: Oct. 21, 2003

(30) Foreign Application Priority Data
Feb. 17, 2003 (JP) 2003-038056

(51) Int. Cl. H01L 27/10

(52) U.S. Cl. 257/202

(57) ABSTRACT

A semiconductor device is provided which can avoid electrical short circuits between contact plugs, connected to gate electrodes, and source/drain regions. Portions of a polysilicon film (7) that are covered by photoresist (8) are left nonetched to form plate-like polysilicon films (10). The polysilicon films (10) are formed on a first portion of an element isolation insulating film (2). The polysilicon films (10) are connected to polysilicon films (9). Contact plugs (24) are formed on the polysilicon films (10). This prevents electrical short circuits between the contact plugs (24) and drain and source regions (5) and (6).

### BACKGROUND OF THE INVENTION

1. Field of the Invention

The present invention relates to a semiconductor device, and particularly to a structure of vertical transistors having sidewall-type gate electrodes, and to a structure of DRAM capacitors using vertical transistors.

2. Description of the Background Art

A conventional vertical transistor has a semiconductor substrate, a recessed portion formed partially in the upper surface of an element formation region of the semiconductor substrate, a first source/drain region formed in the bottom of the recessed portion, a second source/drain region formed in the upper surface of the semiconductor substrate where the recessed portion is not formed, and a sidewall-type gate electrode formed on a side of the recessed portion with a gate insulating film sandwiched between them (for example, refer to Japanese Patent Application Laid-Open No. 10-65160 (1998)).

The conventional vertical transistor has a problem that, when a contact plug connected to the gate electrode is formed within the element formation region, then an electrical short circuit may occur between the contact plug and the first or second source/drain region.

### SUMMARY OF THE INVENTION

Concerning vertical transistors and DRAM capacitors using vertical transistors, an object of the invention is to provide a semiconductor device which can avoid electrical short circuits between contact plugs, connected to gate electrodes, and source/drain regions.

According to the present invention, a semiconductor device includes a semiconductor substrate, an element isolation insulating film, a recessed portion, and a first transistor. The element isolation insulating film is partially formed in a main surface of the semiconductor substrate and defines an element formation region. The recessed portion is formed by trenching part of a main surface of a first region of the semiconductor substrate in the element formation region and part of a main surface of the element isolation insulating film that is connected to that part of the semiconductor substrate. The first transistor is formed in the first region. The semiconductor substrate in the element formation region includes a first portion where the recessed portion is formed and a second portion where the recessed portion is not formed. The element isolation insulating film includes a first portion where the recessed portion is formed to be connected to the first portion of the semiconductor substrate and a second portion where the recessed portion is not formed to be connected to the second portion of the semiconductor substrate. The first transistor includes a channel formation region, a first source/drain region, a second source/drain region and a gate structure. The channel formation region is formed in a side of the second portion of the semiconductor substrate. The first source/drain region is formed in the first portion of the semiconductor substrate. The second source/drain region is formed in the second portion of the semiconductor substrate. The first source/drain region and the second source/drain region are disposed opposite to each other with the channel formation region interposed therebetween. The gate structure is formed on the side of the second portion of the semiconductor substrate and the side of the second portion of the element isolation insulating film. Further, the gate structure extends on the first portion of the semiconductor substrate and the first portion of the element isolation insulating film.

A contact plug connected to the gate structure can be formed on the gate structure in a portion located on the first portion of the element isolation insulating film so as to avoid electric short circuits between the contact plug and the first or second source/drain region.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 16 are diagrams showing a sequence of process steps for manufacturing a semiconductor device according to a first preferred embodiment of the invention, where a memory cell region is shown;

FIGS. 17 to 26 are diagrams showing a sequence of process steps for manufacturing the semiconductor device of the first preferred embodiment, where a logic region is shown;

FIGS. 27 and 28 are top views showing the structure of a semiconductor device according to a modification of the first preferred embodiment;

FIGS. 29 to 33 are diagrams showing a sequence of process steps for manufacturing a semiconductor device according to a second preferred embodiment of the invention;

FIG. 34 is a diagram showing the structure of a flat transistor;

FIG. 35 is a section view regarding a position along a line IIIV-IIIV shown in (B) of FIG. 6; and

FIG. 36 is a section view regarding a position along a line IIIVI-IIIVI shown in (B) of FIG. 6.

### DESCRIPTION OF THE PREFERRED EMBODIMENTS

### First Preferred Embodiment

A semiconductor device and a manufacturing method thereof according to a first preferred embodiment of the invention are now described, with a DRAM/logic mixed system LSI.

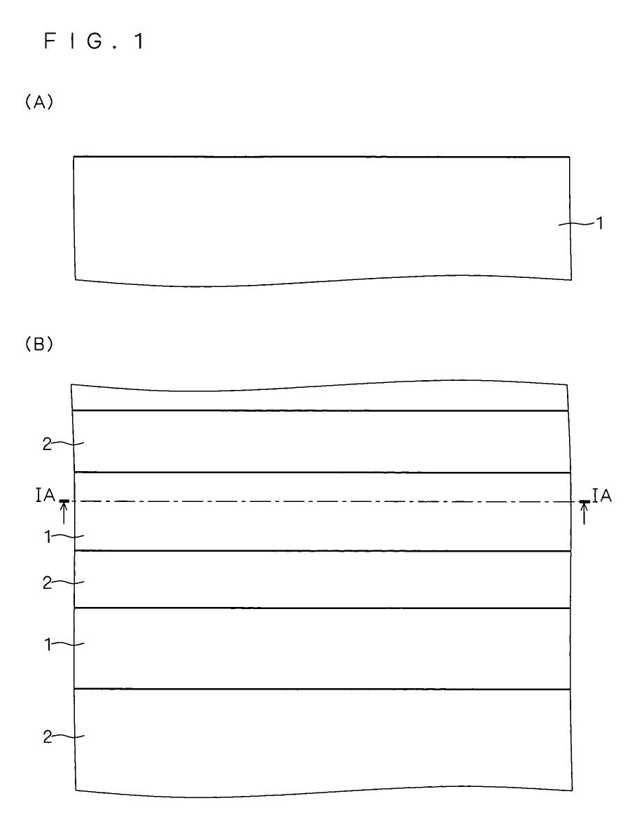

FIGS. 1 to 16 are diagrams showing a sequence of process steps for manufacturing a semiconductor device of the first preferred embodiment, which show a memory cell region where DRAM memory cells are to be formed. The drawings shown at (B) in FIGS. 1 to 16 are top views and the drawings shown at (A) in FIGS. 1 to 16 are the cross-sectional views taken along lines IA to XVIA in the drawings (B) of FIGS. 1 to 16.

First, referring to FIG. 1, element isolation insulating films 2 having a film thickness of about 200 to 400 nm are partially formed in the upper surface of a silicon substrate 1 by a known trench isolation technique. The material of the element isolation insulating films 2 is a silicon oxide film. Next, impurities are ion-implanted into the silicon substrate 1 for well region formation (not shown) and for setting of transistor threshold voltage.

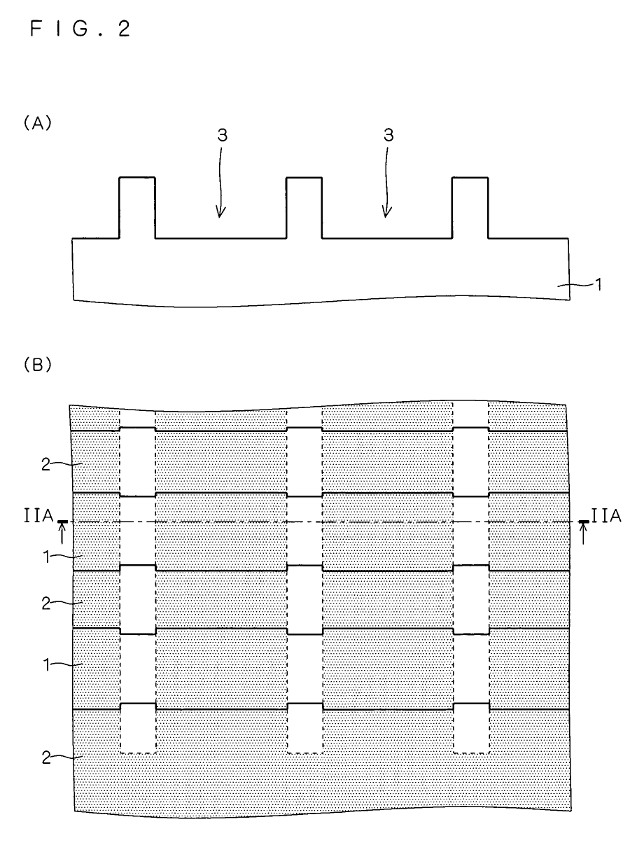

Next, referring to FIG. 2, parts of the upper surface of the silicon substrate 1 and parts of the upper surfaces of the element isolation insulating films 2, which connect with those parts of the upper surface of the silicon substrate 1, are trenched down to a depth of about 50 to 150 nm by photolithography and anisotropic dry-etching, so as to form a recessed portion 3. The area of the recessed portion 3 is hatched in (B) of FIG. 2. In the element formation regions of the silicon substrate 1, the areas where the recessed portion 3 extends are hereinafter referred to as “first portions” and the areas where the recessed portion 3 is absent are referred to as “second portions.” Also, in the element isolation insulating films 2, the areas where the recessed portion 3 extends are referred to as “first portions” and the areas where the recessed portion 3 is absent are referred to as “second portions.” As shown in (A) of FIG. 2, the second portions of the silicon substrate 1 have raised cross sections. Desirably, in order to obtain field effect by a double-gate structure described later, the width (the shorter sides) of the second portions of the silicon substrate 1 is set at 100 nm or less. Though not shown in (A) of FIG. 2, the second portions of the element isolation insulating films 2, too, have similar raised cross sections.

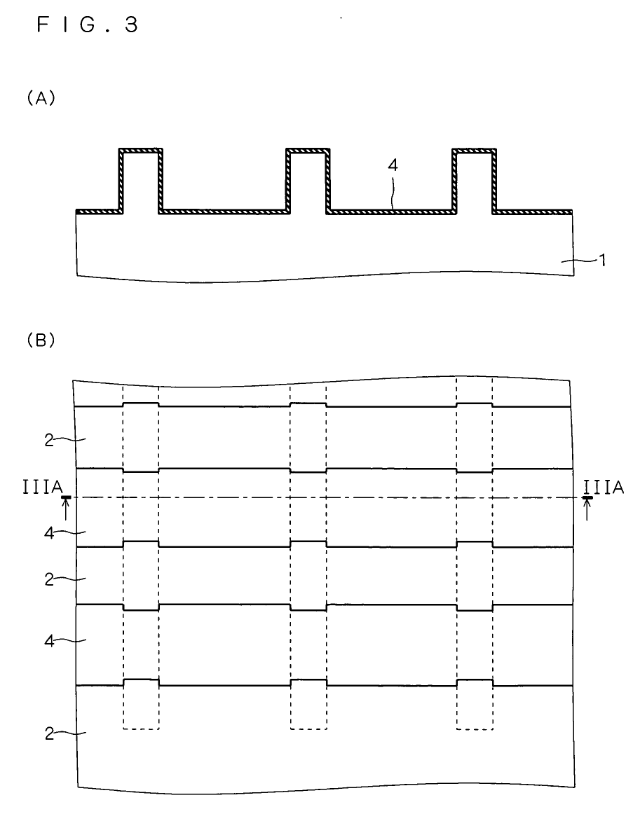

Next, referring to FIG. 3, a silicon oxide film 4 is formed on the surface of the silicon substrate 1 by, e.g. an oxidation process using radicals.

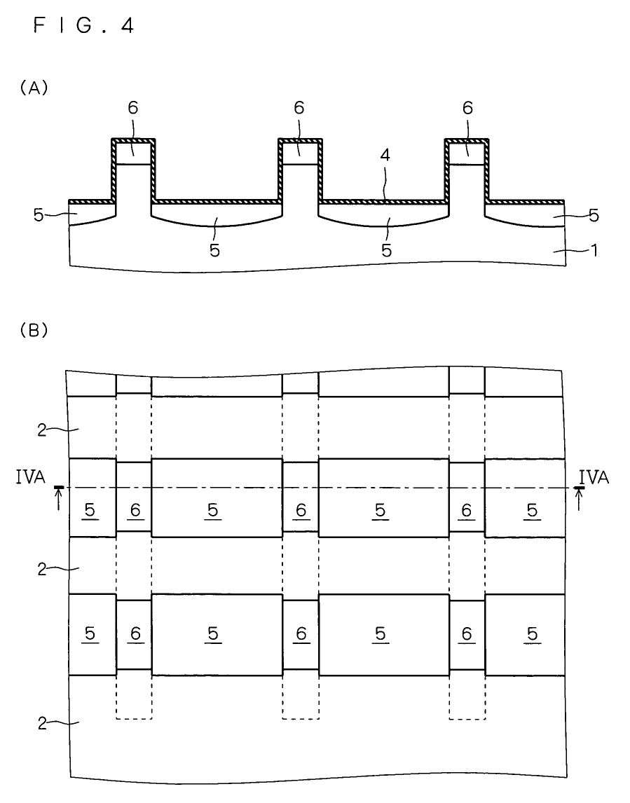

Next, referring to FIG. 4, an impurity, e.g. phosphorus, is ion-implanted into the silicon substrate 1 through the silicon oxide film 4 at an energy of about 10 to 20 keV and a concentration of about 1 to 5×10¹³/cm². This process forms drain regions 5 in the upper surfaces of the first portions of the silicon substrate 1 and source regions 6 in the upper surfaces of the second portions of the silicon substrate 1. Areas at the sides of the second portions of the silicon substrate 1 are defined as channel formation regions; the drain regions 5 and the source regions 6 are disposed opposite to each other with the channel formation regions between them. The drain regions 5 and source regions 6 may be formed after formation of sidewall-type polysilicon films described below.

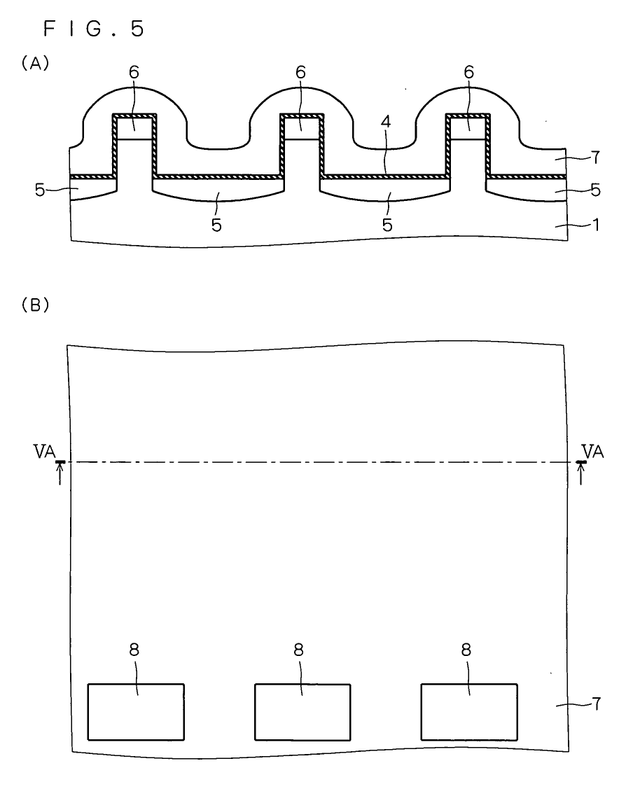

Next, referring to FIG. 5, a polysilicon film 7, which contains an impurity, e.g. phosphorus, at a concentration of about 1 to 5×10²⁰/cm³, is deposited by CVD all over the surface. The thickness of the polysilicon film 7 is about 50 to 150 nm. Next, photoresist 8 is partially applied by photolithography on the polysilicon film 7, above the first portion of an element isolation insulating film 2.

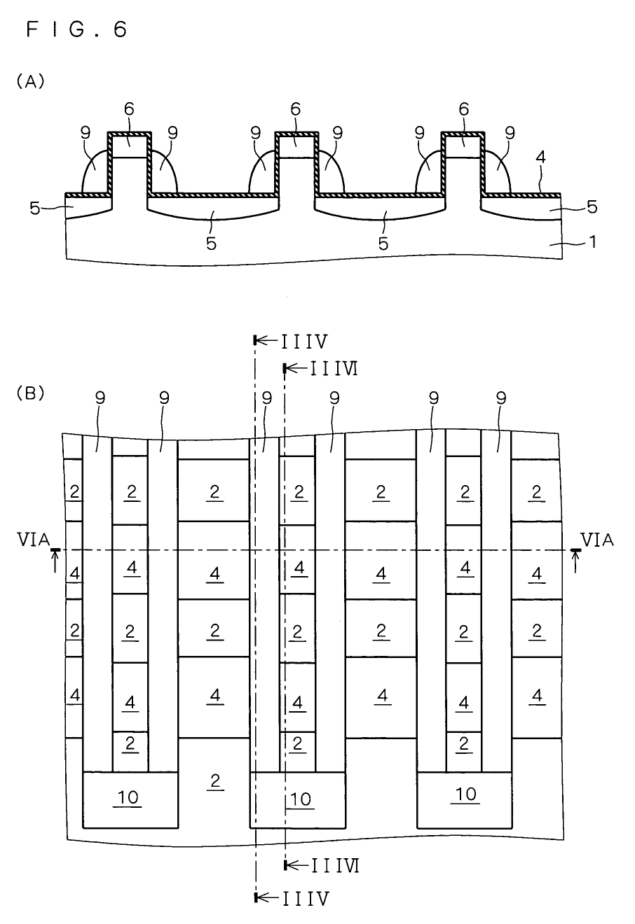

Next, referring to FIG. 6, the polysilicon film 7 is etched back until the silicon oxide film 4 is exposed. Sidewall-type polysilicon films 9 are thus formed, whereby memory cell transistors are completed. During this process, the amount of etching of polysilicon film 7 is controlled so that the overlap between the polysilicon films 9 and the source region 6 is about 0 to 20 nm, for example. The polysilicon films 9 function as gate electrodes. The portions of the silicon oxide film 4 which are sandwiched between the polysilicon films 9 and silicon substrate 1 function as gate insulating films. Each gate structure having the gate electrodes and gate insulating films is formed in contact with the sides of the second portions of the silicon substrate 1 and the sides of the second portions of the element isolation insulating films 2 and extends on the first portions of the silicon substrate 1 and the first portions of the element isolation insulating films 2.

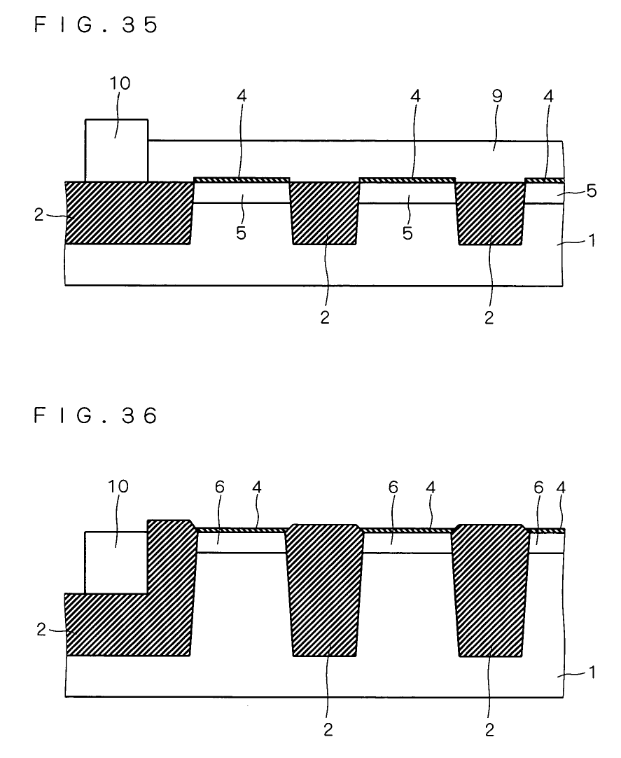

During the etching-back of the polysilicon film 7, the photoresist 8 serves as an etching mask. Therefore the portions of polysilicon film 7 that are covered by the photoresist 8 are not etched and are left as plate-like polysilicon films 10. As shown in (B) of FIG. 6, the polysilicon films 10 are formed on the first portion of an element isolation insulating film 2. Also, the polysilicon films 10 are connected to polysilicon films 9. The photoresist 8 is removed after that. FIG. 35 is a section view regarding a position along a line IIIV-IIIV shown in (B) of FIG. 6. FIG. 36 is a section view regarding a position along a line IIIVI-IIIVI shown in (B) of FIG. 6.

As shown in FIG. 6, in the semiconductor device of the first preferred embodiment, a plurality of memory cell transistors are arranged in a matrix in a first direction (right-left direction on the paper) and a second direction (top-bottom direction on the paper). The element isolation insulating films 2 are disposed between adjacent memory cell transistors arranged in the second direction. Polysilicon films 9 serving as gate electrodes and a polysilicon film 10 connected to the polysilicon films 9 are shared by a plurality of memory cell transistors arranged in the second direction.

The memory cell transistors of the first preferred embodiment adopt a double-gate structure, where the gate structure is formed in contact with both of the two opposite sides of the second portions of the silicon substrate 1. However, it is not essential to adopt the double-gate structure.

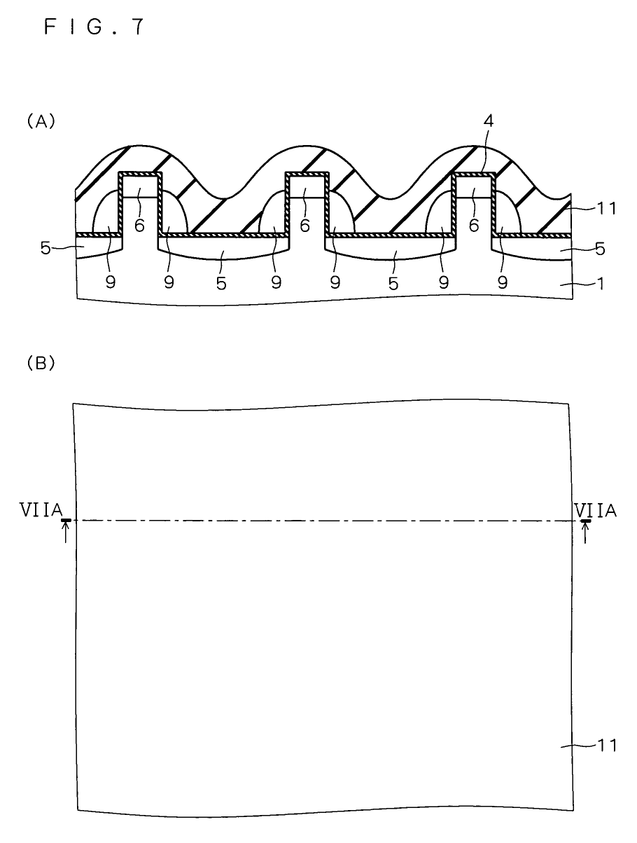

Next, referring to FIG. 7, a silicon nitride film 11 having a thickness of about 50 to 150 nm is deposited by CVD all over the surface.

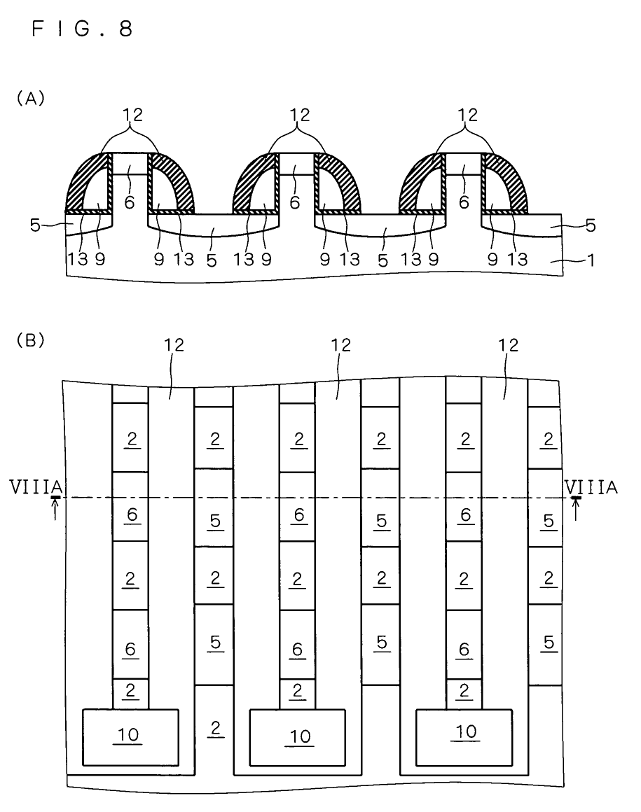

Next, referring to FIG. 8, the silicon nitride film 11 is etched back to form sidewalls 12. The etching process also removes parts of the silicon oxide film 4 to form silicon oxide films 13. Thus the upper surfaces of the source regions 6 and parts of the upper surfaces of the drain regions 5 are exposed. The top surfaces of the polysilicon films 10, too, are exposed by the etching-back of the silicon nitride film 11.

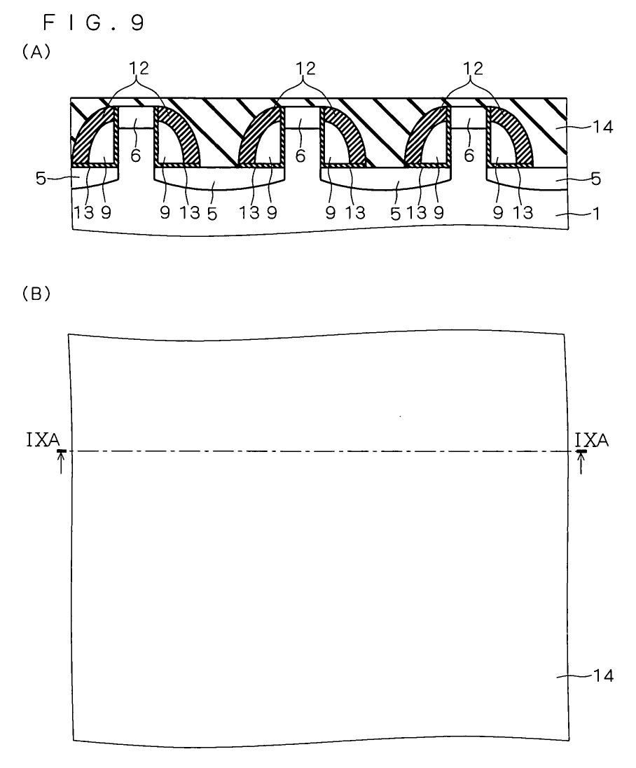

Next, referring to FIG. 9, a silicon oxide film 14 having a thickness of about 200 to 500 nm is deposited by CVD on the entire surface. Next, when required, the top surface of the silicon oxide film 14 is planarized by CMP (Chemical Mechanical Polishing).

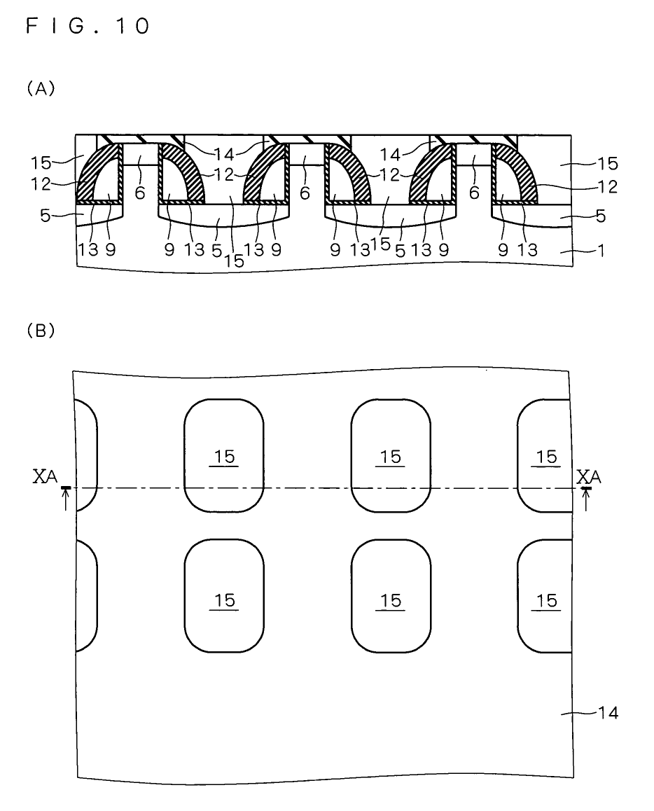

Next, referring to FIG. 10, a photolithography and anisotropic dry-etching process is performed to form, in a self-aligned manner, contact holes to the drain regions 5 through the silicon oxide film 14. Next, a CVD process is performed to form a polysilicon film all over the surface to such a thickness as to completely fill the contact holes. Next, the polysilicon film is etched back to form contact plugs 15.

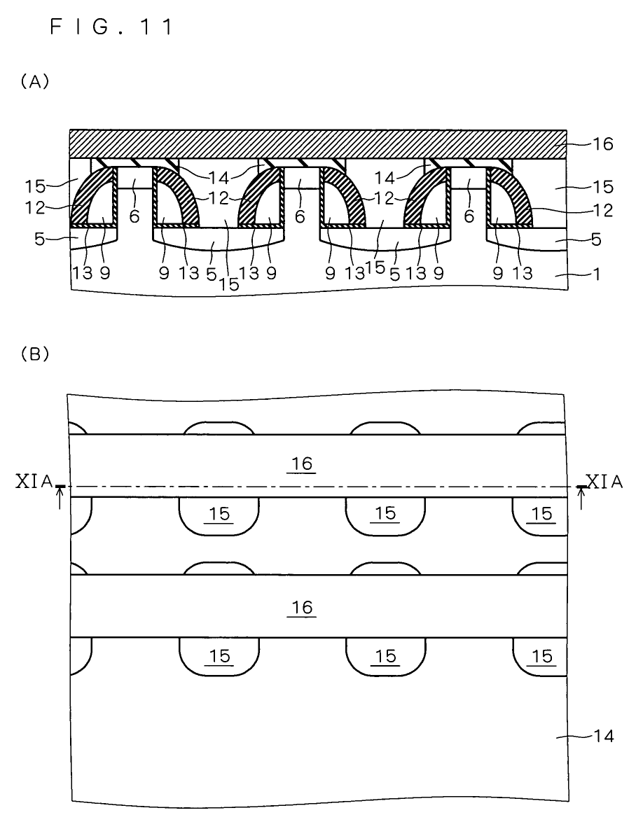

Next, referring to FIG. 11, a tungsten film having a thickness of about 50 to 200 nm is deposited by PVD on the entire surface. Next, the tungsten film is patterned by photolithography and anisotropic dry-etching to form bit lines 16. The bit lines 16 are connected to the contact plugs 15.

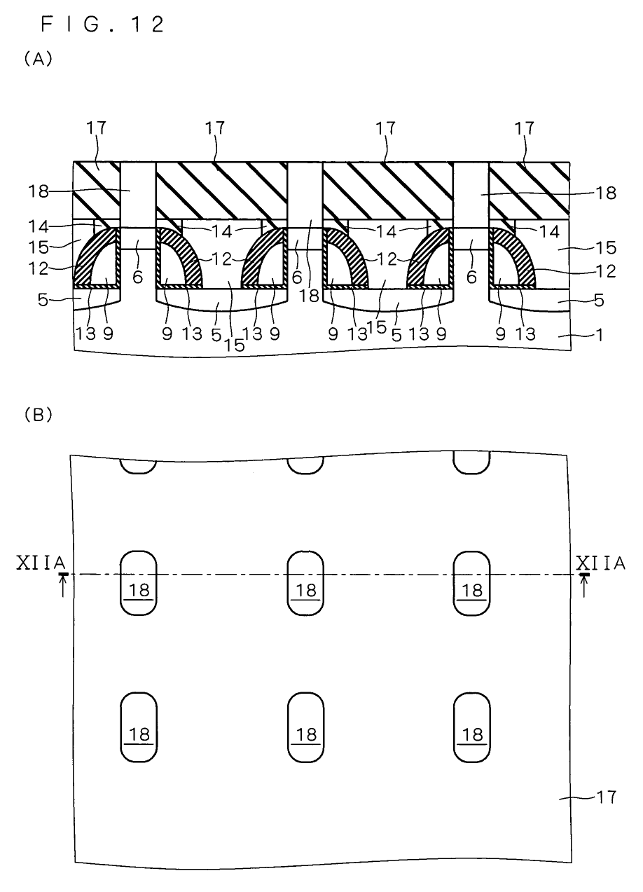

Next, referring to FIG. 12, a silicon oxide film 17 having a thickness of about 200 to 500 nm is deposited by CVD on the entire surface. Next, a photolithography and anisotropic dry-etching process is applied to form contact holes to the source regions 6 through the silicon oxide films 14 and 17. Next, a polysilicon film is formed by CVD on the entire surface to such a thickness as to completely fill the contact holes. Next, the polysilicon film is etched back to form contact plugs 18.

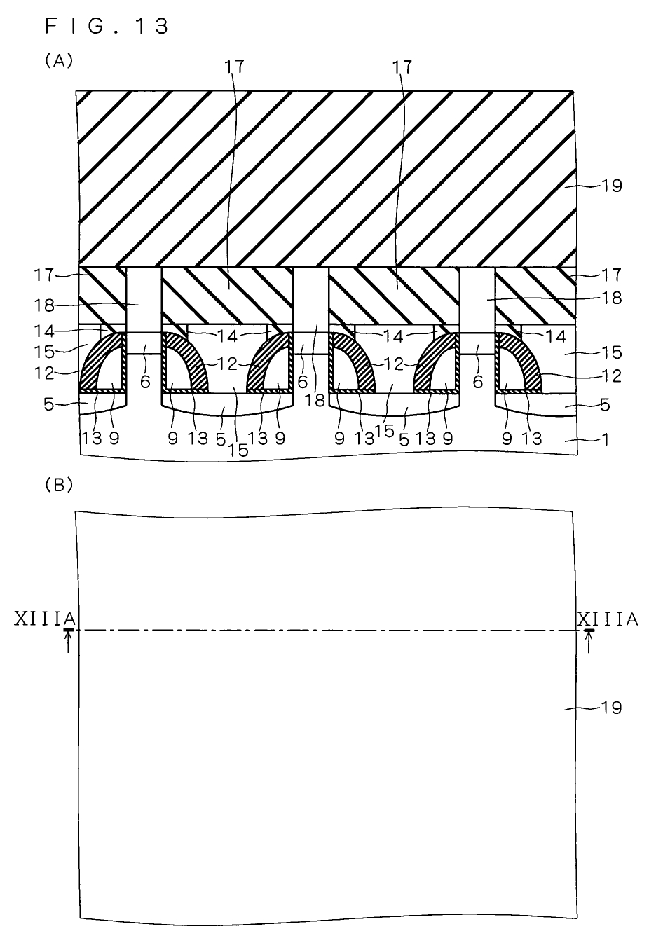

Next, referring to FIG. 13, a silicon oxide film 19 having a thickness of about 500 to 2000 nm is formed by CVD on the entire surface.

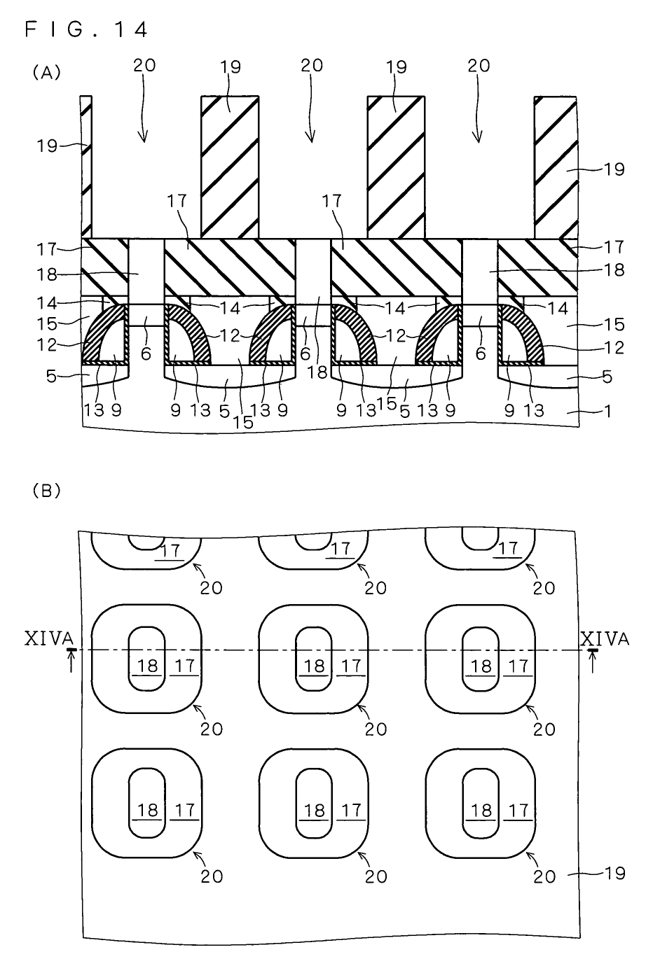

Next, referring to FIG. 14, recesses 20 are formed in the silicon oxide film 19 by photolithography and anisotropic dry-etching. Contact plugs 18 are exposed at the bottoms of the recesses 20.

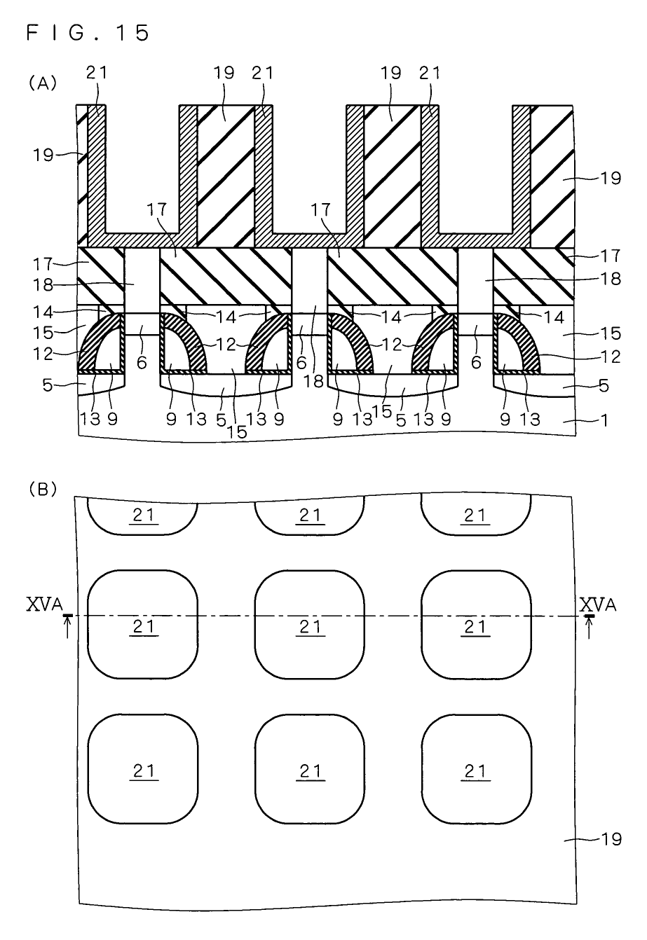

Next, referring to FIG. 15, a conductive film, deposited all over the surface, is patterned to form capacitor lower electrodes 21. The capacitor lower electrodes 21 are formed on the sides and bottoms of the recesses 20 and are in contact with the top surfaces of the contact plugs 18.

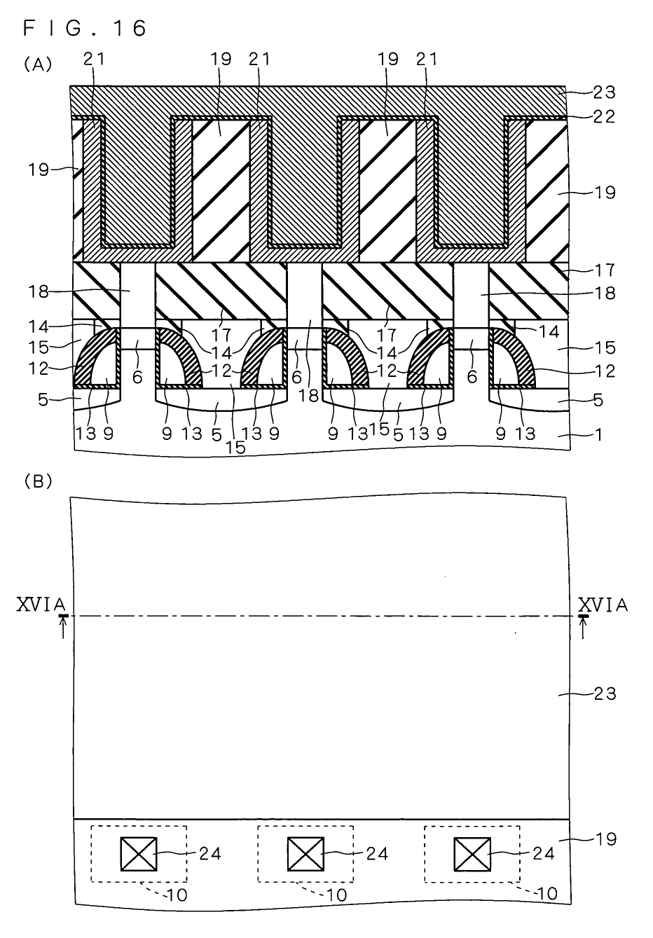

Next, referring to FIG. 16, an insulating film and a conductive film are sequentially formed over the entire surface and then patterned to form capacitor dielectric film 22 and capacitor upper electrode 23. DRAM capacitors are thus completed. The capacitor upper electrode 23 is disposed opposite to the capacitor lower electrodes 21 with the capacitor dielectric film 22 interposed between them.

Then interconnecting process is carried out to complete the semiconductor device. The interconnecting process forms a plurality of contact plugs connecting upper interconnection layers (not shown) with the bit lines 16, polysilicon films 9 serving as gate electrodes, and capacitor upper electrode 23. The portion (B) of FIG. 16 shows contact plugs 24 for connecting upper interconnection layer and the polysilicon films 9. The contact plugs 24 are formed in the silicon oxide films 14, 17 and 19. Also, the contact plugs 24 are formed on the polysilicon films 10. The upper interconnection layer is connected to the polysilicon films 9 through the contact plugs 24 and the polysilicon films 10.

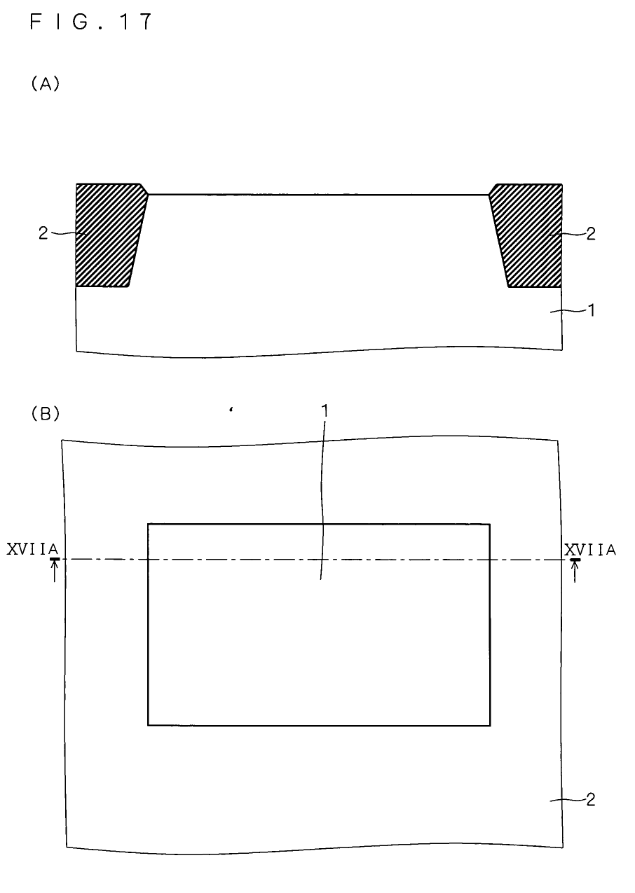

FIGS. 17 to 26 are diagrams showing a sequence of process steps for manufacturing the semiconductor device of the first preferred embodiment, where a logic region in which logic circuitry is to be formed is shown. The drawings shown at (B) in FIGS. 17 to 26 are top views and the drawings shown at (A) in FIGS. 17 to 26 are the cross-sectional views taken along lines XVIIA to XXVIA in the drawings (B) of FIGS. 17 to 26.

The process step shown in FIG. 17 is performed as the same process step as that shown in FIG. 1. Element isolation insulating films 2 are partially formed in the upper surface of the silicon substrate 1.

While the process step of FIG. 2 is being carried out, the logic region is covered by photoresist. Therefore recessed portion 3 is not formed in the logic region. The photoresist is removed after the formation of recessed portion 3 in the memory cell region has been completed.

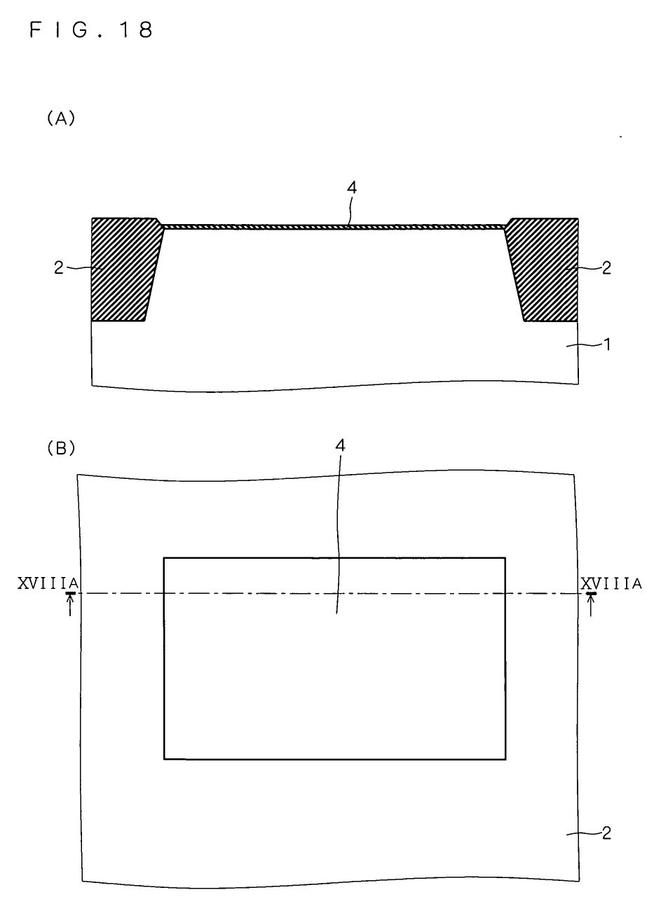

The process step shown in FIG. 18 is carried out as the same process step as that shown in FIG. 3. Silicon oxide film 4 is formed on the upper surface of the silicon substrate 1 in the element formation region. As stated earlier, the silicon oxide film 4 is formed by oxidation using radicals. Oxidation with radicals provides an almost uniform oxidizing rate in all directions, independently of surface orientation. This causes the silicon oxide film 4 to form to an equal thickness in the memory cell region and the logic region.

While the step of FIG. 4 is being carried out, the logic region is covered by photoresist. Therefore drain regions 5 and source regions 6 are not formed in the logic region. The photoresist is removed after the completion of formation of the drain regions 5 and source regions 6 in the memory cell region.

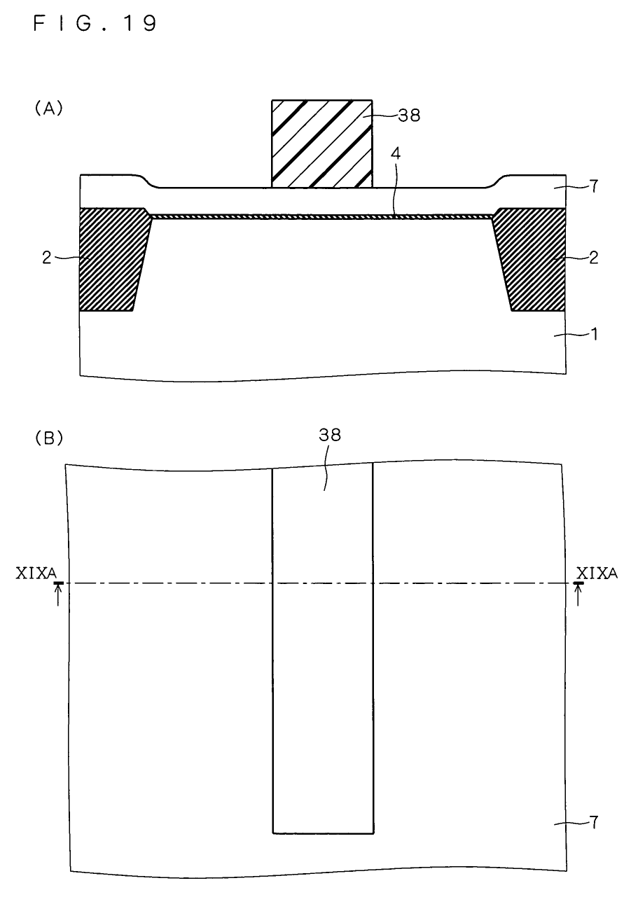

The process step shown in FIG. 19 is performed as the same process step as that shown in FIG. 5. Polysilicon film 7 is formed all over the surface. Also, photoresist 38 is partially formed on the polysilicon film 7. The photoresist 38 is formed by the photolithography process for forming the photoresist 8.

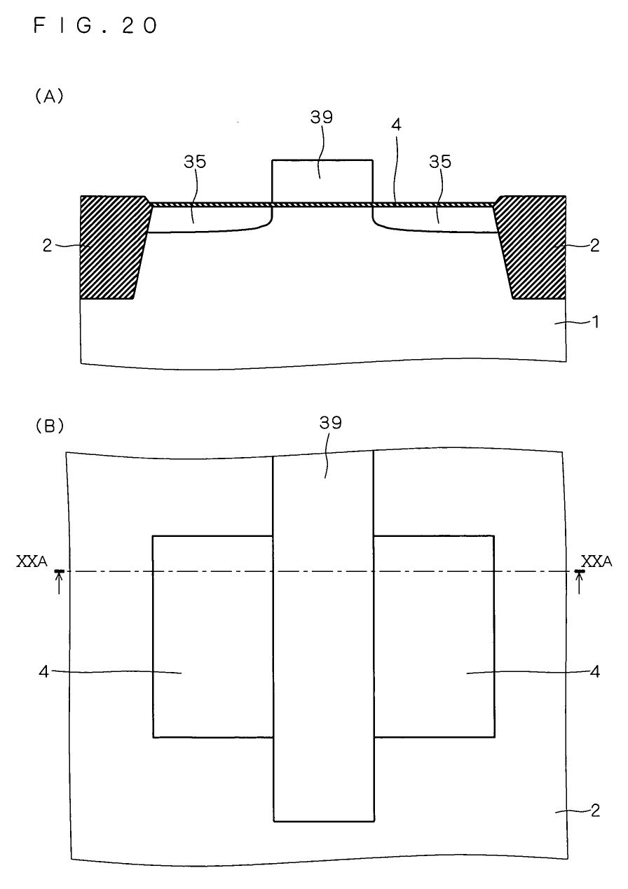

The process step shown in FIG. 20 is performed as the same process step as that shown in FIG. 6. The polysilicon film 7 is patterned to form a polysilicon film 39 serving as a gate electrode. Next, an ion implantation process is performed to implant an impurity, e.g. phosphorus, into the silicon substrate 1 through the silicon oxide film 4, at an energy of about 10 to 20 keV and a concentration of about 1 to 5×10¹³/cm². This process forms a pair of source/drain regions 35 with the channel formation region, under the gate electrode, interposed between them. During this ion implantation process, the memory cell region is covered by photoresist. Therefore source/drain regions 35 are not formed in the memory cell region. Note that the drain regions 5 and source regions 6 may be formed not by the process step of FIG. 4 but by the ion implantation process for formation of source/drain regions 35; i.e. the drain regions 5 and source regions 6 may be formed together with the source/drain regions 35 by not covering the memory cell region with photoresist during the ion implantation process for formation of the source/drain regions 35.

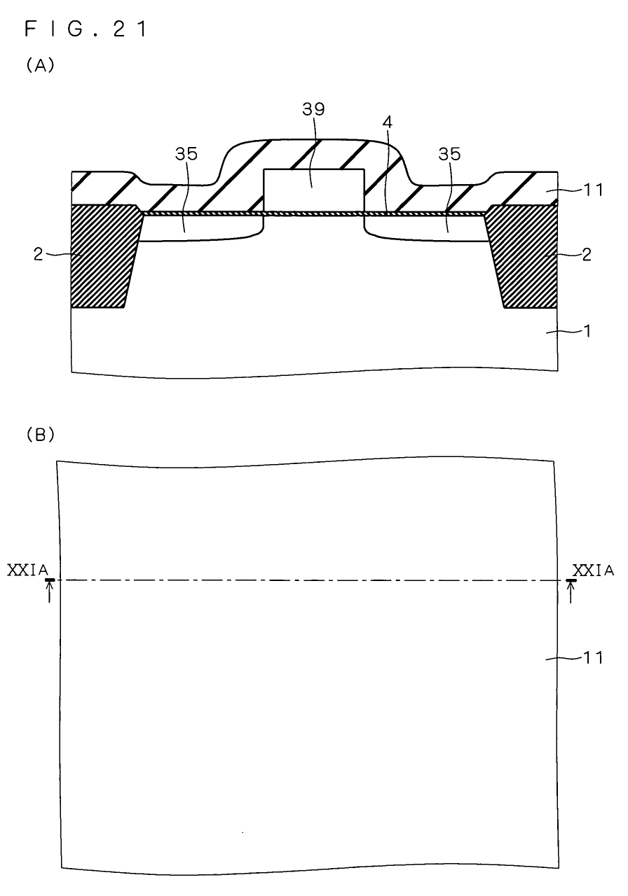

The process step shown in FIG. 21 is performed as the same step as that shown in FIG. 7. Silicon nitride film 11 is formed all over the surface.

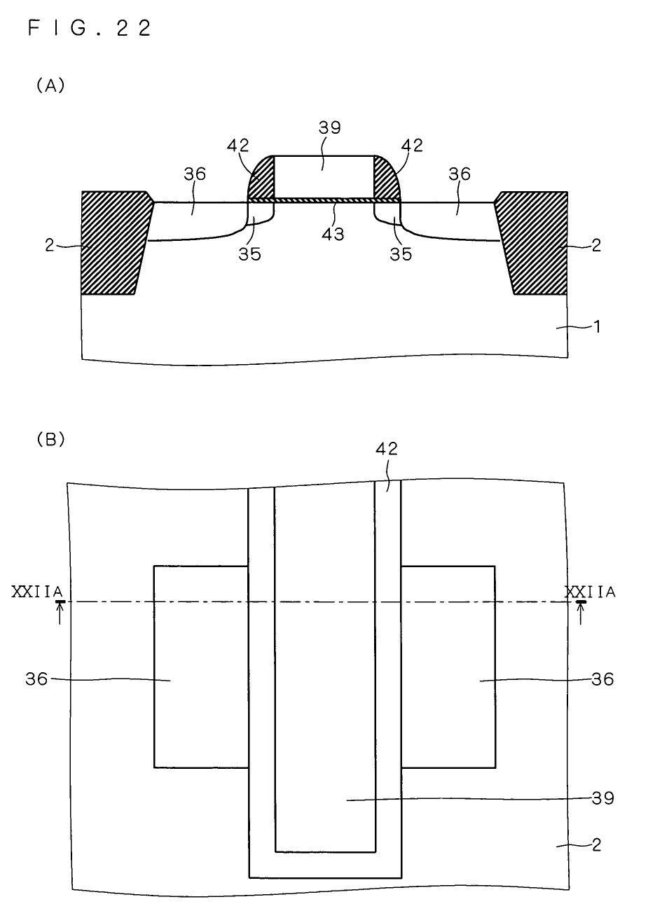

The process step shown in FIG. 22 is performed as the same step as that shown in FIG. 8. The silicon nitride film 11 is etched back to form sidewalls 42 on the sides of the polysilicon film 39. This etching process partially removes the silicon oxide film 4 to form silicon oxide film 43 serving as a gate insulating film. Next, an impurity, e.g. arsenic, is ion-implanted into the silicon substrate 1 at an energy of about 10 to 50 keV and a concentration of about 1 to 5×10¹⁵/cm². Thus source/drain regions 36 are formed in the upper surface of the silicon substrate 1, whereby a flat transistor is completed in the logic circuit. The memory cell region is covered by photoresist during this ion implantation process. Therefore source/drain regions 36 are not formed in the memory cell region. The photoresist is removed after the completion of formation of the source/drain regions 36 in the logic region.

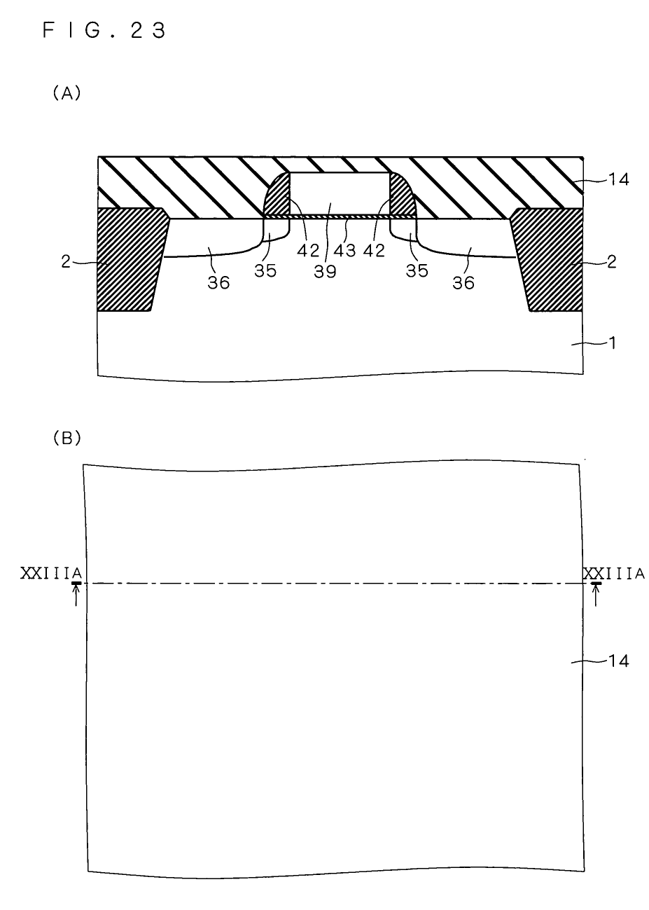

The process step shown in FIG. 23 is performed as the same step as that shown in FIG. 9. Silicon oxide film 14 is formed all over the surface.

During the process steps shown in FIGS. 10 and 11, contact plugs 15 and bit lines 16 are not formed in the logic region.

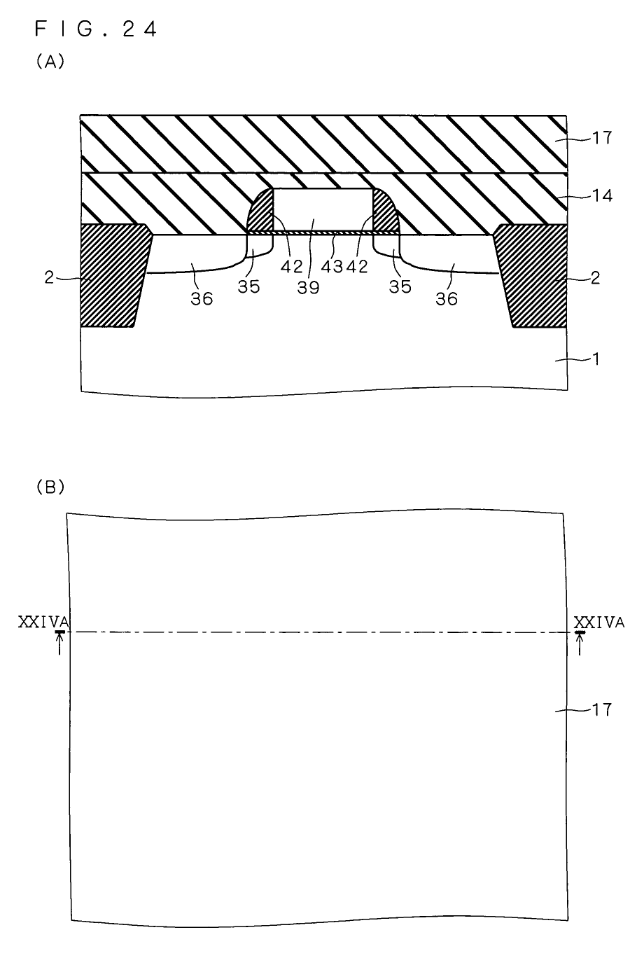

The process step shown in FIG. 24 is performed as the same step as that shown in FIG. 12. Silicon oxide film 17 is formed all over the surface. Note that contact plugs 18 are not formed in the logic region.

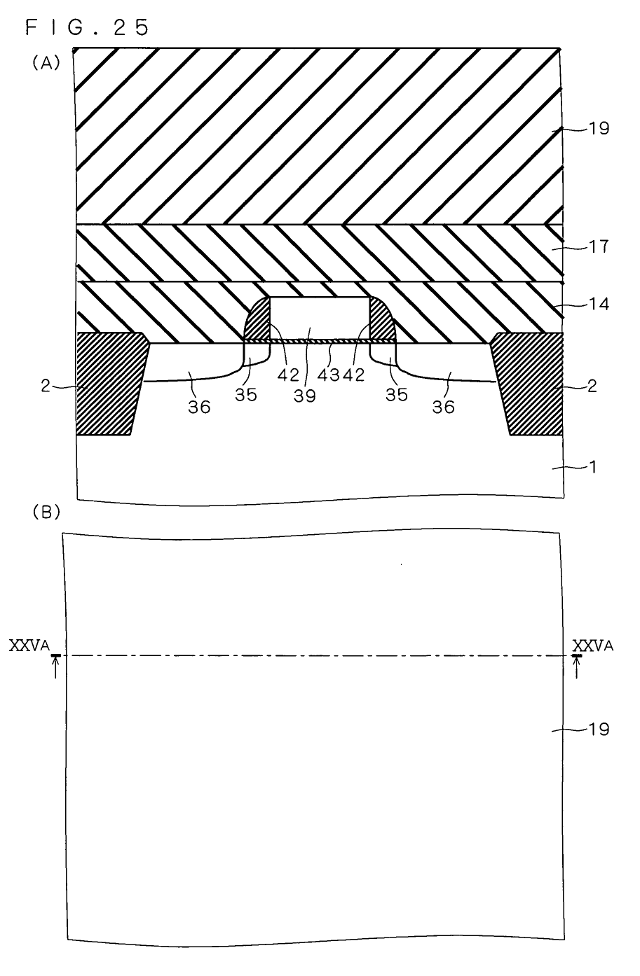

The process step shown in FIG. 25 is performed as the same step as that shown in FIG. 13. Silicon oxide film 19 is formed all over the surface.

During the process steps shown in FIGS. 14 to 16, recesses 20, capacitor lower electrodes 21, capacitor dielectric film 22, and capacitor upper electrode 23 are not formed in the logic region.

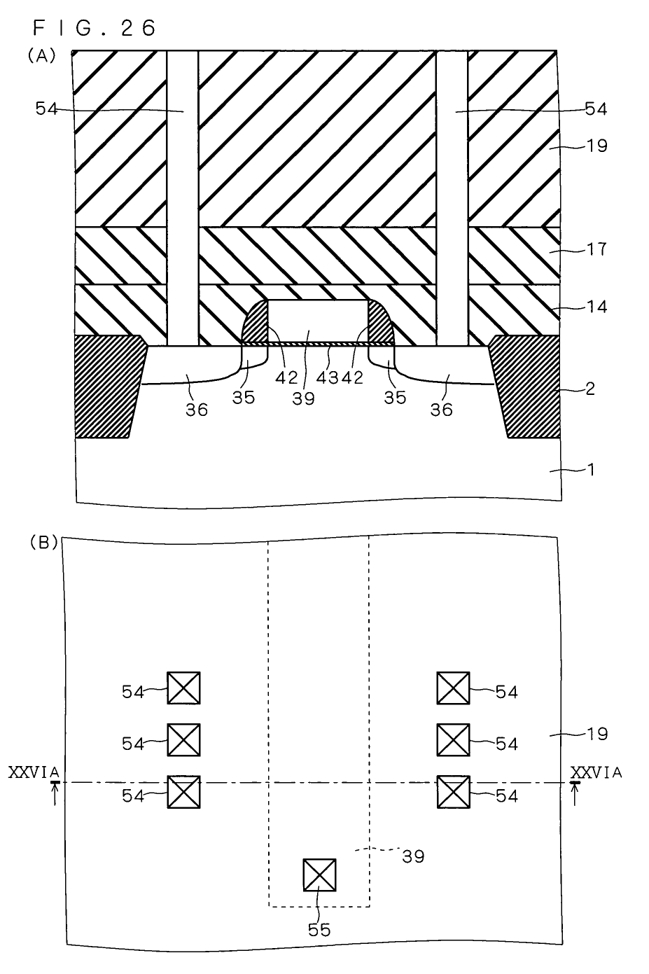

Referring to FIG. 26, a process step for forming contact plugs 54 and 55 is performed as the same process step as that for forming the contact plugs 24 shown in FIG. 16. The contact plugs 54 are connected to the source/drain regions 36. The contact plug 55 is connected to the polysilicon film 39 serving as a gate electrode.

In this way, according to the semiconductor device and manufacturing method of the first preferred embodiment, the contact plugs 24 connected to the gate structures are formed on the portions of the gate structures that are located on the first portion of an element isolation insulating film 2. This arrangement prevents electrical short circuits between the contact plugs 24 and the drain and source regions 5 and 6.

Also, it is possible to form vertical transistors and flat transistors using the same silicon substrate 1. Furthermore, it is possible to reduce the area of each single memory cell transistor in DRAM memory cells, which allows a higher degree of integration. Moreover, since the memory cell transistors adopt the double-gate structure, it is possible to suppress leakage of charges from capacitors even when capacitor capacitance is reduced because of miniaturization, making it possible to keep good data storage characteristics.

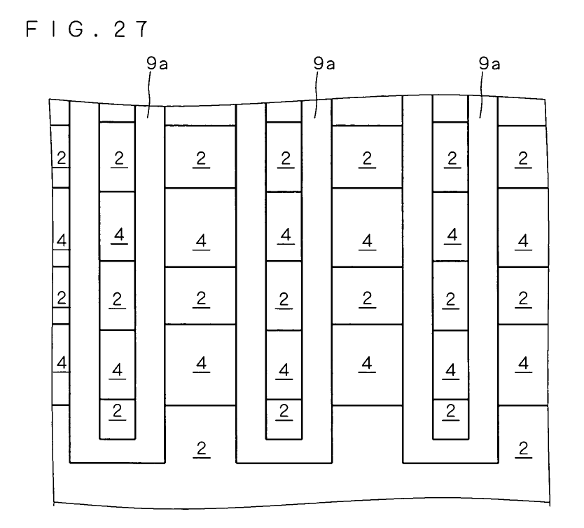

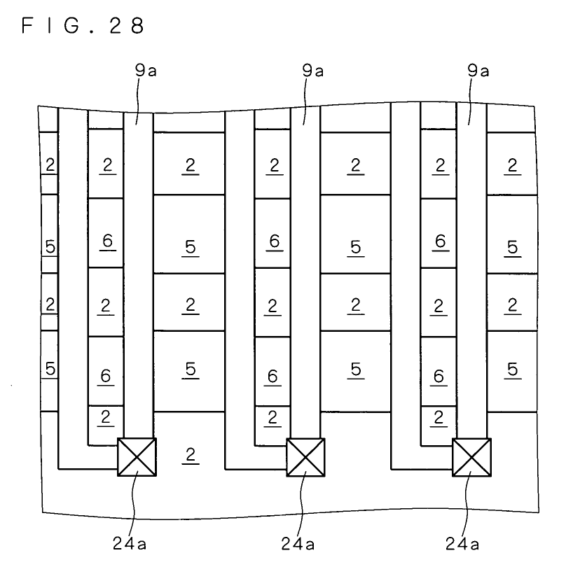

FIGS. 27 and 28 are top views showing the structure of a semiconductor device of a modification of the first preferred embodiment. Referring to FIG. 27, the plate-like polysilicon films 10 of FIG. 6 are absent and each sidewall-type polysilicon film 9a is formed along the periphery of the structure composed of second portions of the silicon substrate 1 and second portions of the element isolation insulating films 2.

Referring to FIG. 28, contact plugs 24a are formed in place of the contact plugs 24 (FIG. 16) that were formed on the polysilicon films 10. The contact plugs 24a are formed on the gate structures in portions that are located on the first portion of an element isolation insulating film 2.

The semiconductor device of the modification of the first preferred embodiment, too, can avoid electrical short circuits between the contact plugs 24a and the drain and source regions 5 and 6.

### Second Preferred Embodiment

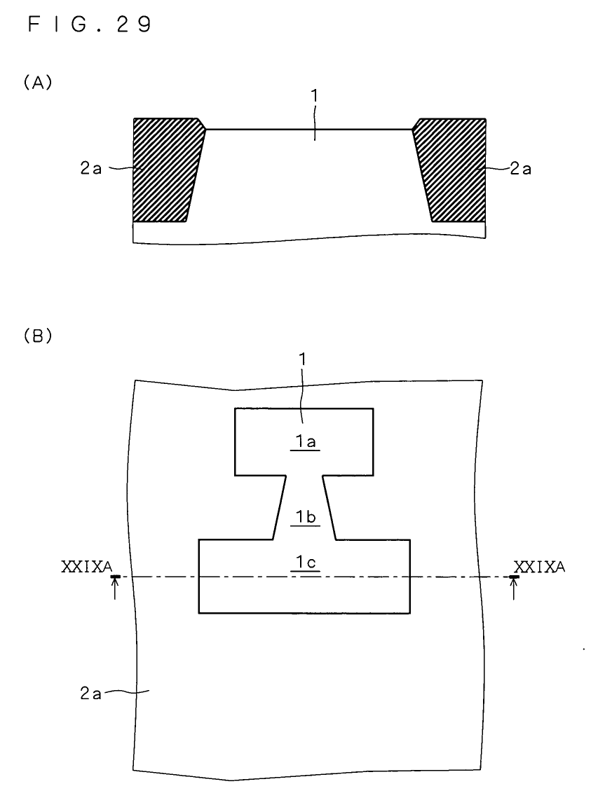

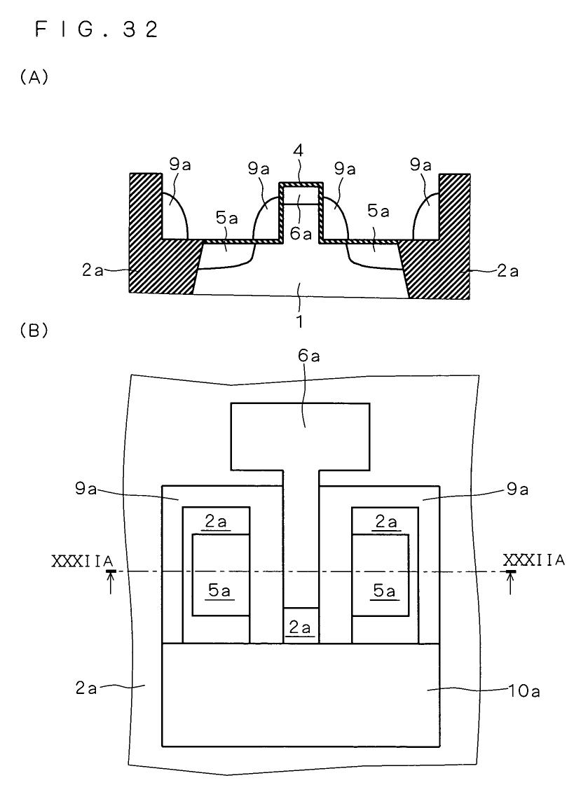

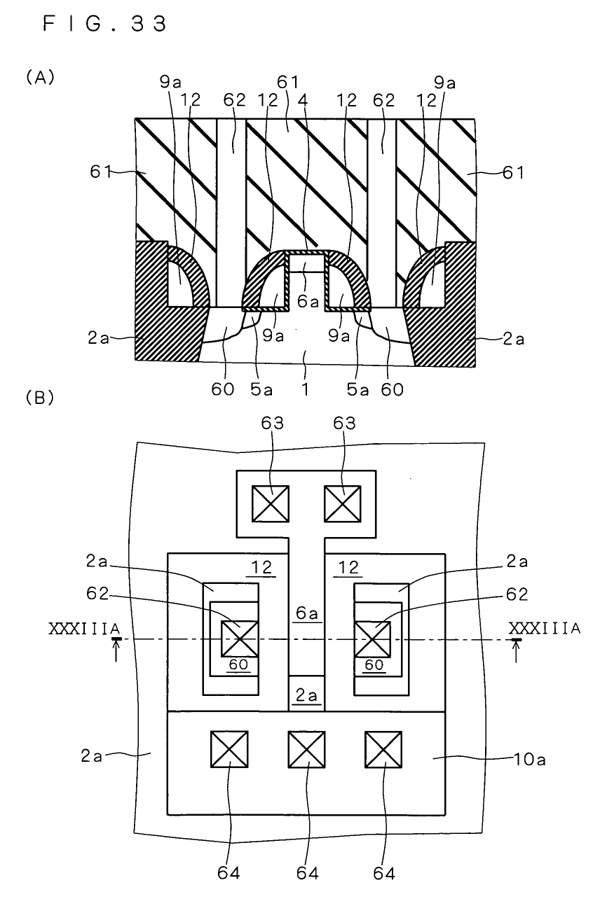

FIGS. 29 to 33 are diagrams showing a sequence of process steps for manufacturing a semiconductor device according to a second preferred embodiment of the invention, where a first region in which vertical transistors are formed is shown. The drawings shown at (B) in FIGS. 29 to 33 are top views and the drawings shown at (A) in FIGS. 29 to 33 are the cross-sectional views taken along lines XXIXA to XXXIIIA in (B) of FIGS. 29 to 33. Note that the top view (B) of FIG. 32 does not show silicon oxide film 4 and (B) of FIG. 33 does not show silicon oxide film 61.

First, referring to FIG. 29, an element isolation insulating film 2a having a film thickness of about 200 to 400 nm is partially formed in the upper surface of a silicon substrate 1 by a known trench isolation technique. As shown in (B) of FIG. 29, the element formation region defined by the element isolation insulating film 2a has a first portion 1a, a second portion 1b, and a third portion 1c. The first portion 1a and the second portion 1b protrude from the third portion 1c. The first portion 1a and the third portion 1c are connected to each other through the second portion 1b. The second portion 1b has a tapered top surface where the width of the side adjoining the third portion 1c is larger than the width of the side adjoining the first portion 1a. Next, impurities are ion-implanted into the silicon substrate 1 for well region formation (not shown) and for setting of transistor threshold voltage.

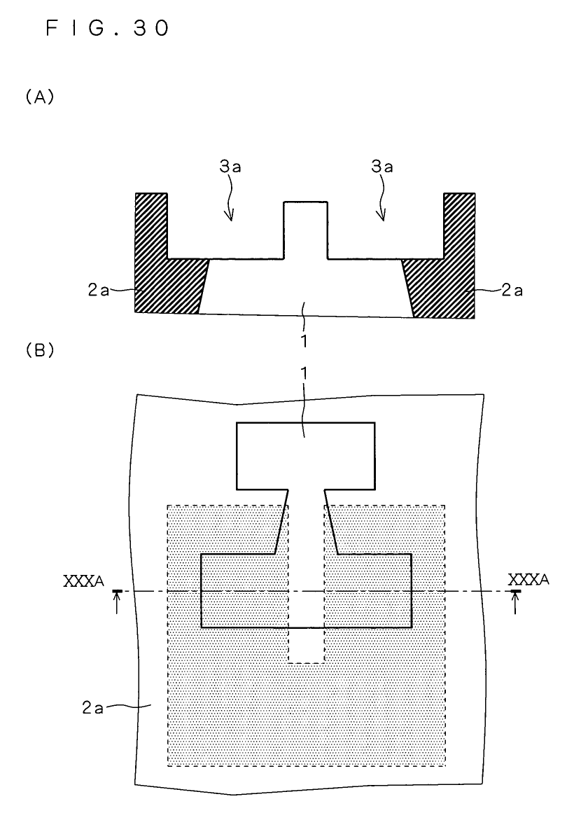

Next, referring to FIG. 30, part of the upper surface of the silicon substrate 1 and part of the upper surface of the element isolation insulating film 2a that is connected to that part of the silicon substrate 1 is trenched to a depth of about 50 to 150 nm by photolithography and anisotropic dry-etching, so as to form a recessed portion 3a. The area of the recessed portion 3a is hatched in (B) of FIG. 30. It is desirable to set the width of the second portion of the silicon substrate 1 at 100 nm or less, in order to obtain field effect by the double-gate structure. As shown in (B) of FIG. 29, the top surface of the second portion 1b of the element formation region is taper-shaped. This avoids the problem that some part may not be double-gate structured, even if photomask alignment in the photolithography process for forming the recessed portion 3a is somewhat shifted in the transverse direction on the paper.

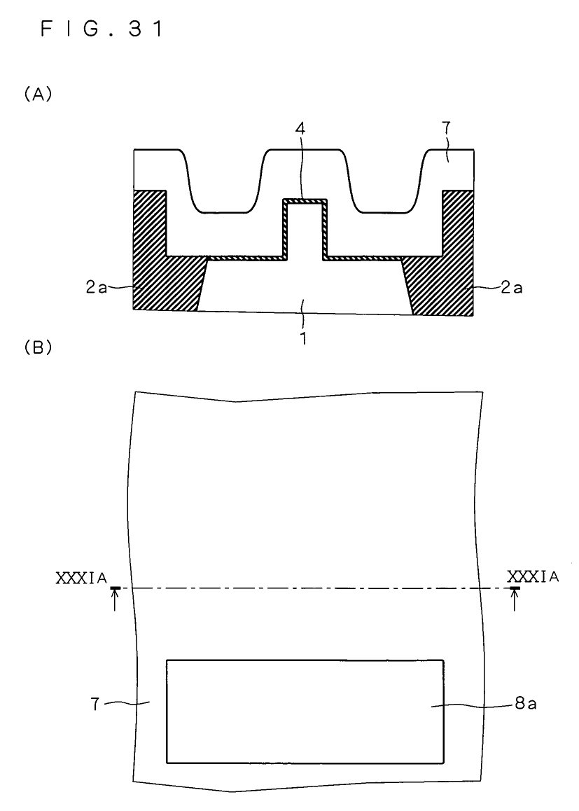

Next, referring to FIG. 31, a silicon oxide film 4 is formed on the surface of the silicon substrate 1 by, e.g. an oxidation process using radicals. Next, a polysilicon film 7 containing an impurity, e.g. phosphorus, at a concentration of about 1 to 5×10²⁰/cm³ is deposited by CVD on the entire surface. The film thickness of the polysilicon film 7 is about 50 to 150 nm. Next, photoresist 8a is partially applied on the polysilicon film 7 by photolithography, above the first portion of the element isolation insulating film 2.

Next, referring to FIG. 32, the polysilicon film 7 is etched back until the silicon oxide film 4 is exposed. This process forms sidewall-type polysilicon films 9a serving as gate electrodes. The photoresist 8a serves as an etching mask during the etching-back of the polysilicon film 7. Therefore a plate-like polysilicon film 10a is formed, as part of the polysilicon film 7 that is covered by the photoresist 8a and so left nonetched. As shown in (B) of FIG. 32, the polysilicon film 10a is formed on the first portion of the element isolation insulating film 2a. The polysilicon film 10a is connected to the polysilicon films 9a. The photoresist 8a is removed after that.

Next, an ion implantation process is performed to implant an impurity, e.g. phosphorus, into the silicon substrate 1 through the silicon oxide film 4 at an energy of about 10 to 20 keV and a concentration of about 1 to 5×10¹³/cm². This process forms source/drain regions 5a and 6a. The ion implantation for forming the source/drain regions 5a and 6a may be performed in the process step shown in FIG. 31, after the formation of the silicon oxide film 4 and before the deposition of the polysilicon film 7.

Next, referring to FIG. 33, a silicon nitride film having a film thickness of about 50 to 150 nm is deposited by CVD on the entire surface. Next, the silicon nitride film is etched back to form sidewalls 12. Next, an impurity, e.g. arsenic, is ion-implanted into the silicon substrate 1 at an energy of about 10 to 50 keV and a concentration of about 1 to 5×10¹⁵/cm². This process forms source/drain regions 60 and completes the vertical transistors. Next, a silicon oxide film 61 is deposited all over the surface and then contact plugs 62 to 64 are formed in the silicon oxide film 61. The contact plugs 62 are connected to the source/drain regions 60. The contact plugs 63 are connected to the source/drain region 6a. The contact plugs 64 are connected to the polysilicon film 10a.

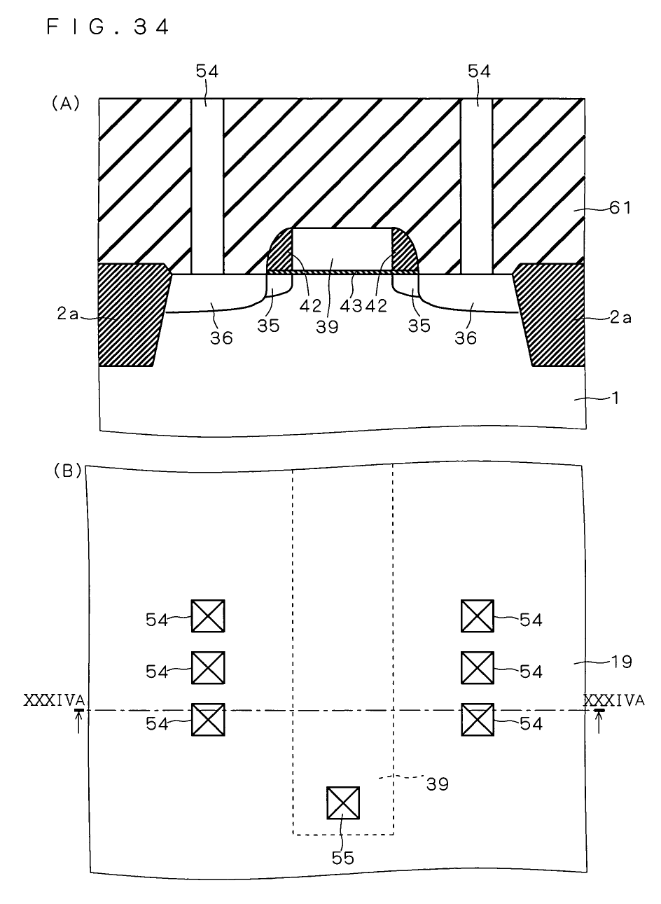

In the second preferred embodiment, as in the first preferred embodiment, a flat transistor may be formed in another, second region, separate from the first region where vertical transistors are formed. FIG. 34 shows the structure of a transistor formed in the second region of the silicon substrate 1. The drawing shown at (B) in FIG. 34 is a top view and the drawing shown at (A) in FIG. 34 shows the cross-section taken along line XXXIVA in (B) of FIG. 34.

The silicon oxide film 43 serving as the gate insulating film is formed by the same process step with the silicon oxide film 4 shown in FIG. 31. The polysilicon film 39 serving as the gate electrode is formed in the same process step with the polysilicon films 9a and 10a shown in FIG. 32. The sidewalls 42 are formed by the same process step with the sidewalls 12 of FIG. 33. The source/drain regions 35 are formed by the same process step with the source/drain regions 5a and 6a shown in FIG. 32. The source/drain regions 36 are formed by the same process step with the source/drain regions 60 shown in FIG. 33. The contact plugs 54 and 55 are formed by the same process step with the contact plugs 62 to 64 shown in FIG. 33.

In this way, according to the semiconductor device and manufacturing method of the second preferred embodiment, the contact plugs 64, connected to the gate structure, are formed on the portion of the gate structure that is located on the first portion of the element isolation insulating film 2a. As in the first preferred embodiment, this prevents electrical short circuits between the contact plugs 64 and the source/drain regions 5a and 6a.

Further, the source/drain region 6a has a projection that corresponds to the first portion 1a and the second portion 1b of the element formation region (see FIG. 29), and the contact plugs 63 are connected to the projection. It is therefore easy to form interconnections connected to the contact plugs 63 without causing electrical short circuits with interconnections connected to the contact plugs 62 and 64.

Vertical transistors and flat transistors can be formed using the same silicon substrate. Further, since the vertical transistors adopt double-gate structure, leakage current is suppressed and power consumption is reduced as a result.

While the invention has been described in detail, the foregoing description is in all aspects illustrative and not restrictive. It is understood that numerous other modifications and variations can be devised without departing from the scope of the invention.

What is claimed is:

1. A semiconductor device comprising:
a semiconductor substrate;
an element isolation insulating film partially formed in a main surface of said semiconductor substrate and defining an element formation region;
a recessed portion formed by trenching part of said main surface of said semiconductor substrate of a first region in said element formation region and part of a main surface of said element isolation insulating film that is connected to said part of said semiconductor substrate; and
a first transistor formed in said first region,
wherein said semiconductor substrate in said element formation region includes a first portion where said recessed portion is formed and a second portion where said recessed portion is not formed, and
said element isolation insulating film includes a first portion where said recessed portion is formed to be connected to said first portion of said semiconductor substrate and a second portion where said recessed portion is not formed to be connected to said second portion of said semiconductor substrate,
said first transistor includes:
a channel formation region formed in a side of said second portion of said semiconductor substrate;
a first source/drain region formed in said first portion of said semiconductor substrate and a second source/drain region formed in said second portion of said semiconductor substrate that are disposed opposite to each other with said channel formation region interposed therebetween; and
a gate structure formed on said side of said second portion of said semiconductor substrate and a side of said second portion of said element isolation insulating film and extends on said first portion of said semiconductor substrate and said first portion of said element isolation insulating film.

2. The semiconductor device according to claim 1, further comprising a first contact plug formed on said gate structure in a portion located on said first portion of said element isolation insulating film.

3. The semiconductor device according to claim 1, further comprising a plate-like conductive film partially formed on said first portion of said element isolation insulating film and connected to said gate structure.

4. The semiconductor device according to claim 3, further comprising a first contact plug formed on said plate-like conductive film.

5. The semiconductor device according to claim 3,
wherein said second portion of said semiconductor substrate has a projecting portion projecting from said second portion of said semiconductor substrate in a direction opposite to said second portion of said element isolation insulating film, and
said semiconductor device further comprises a second contact plug formed on said projecting portion.

6. The semiconductor device according to claim 3, further comprising:
a second contact plug formed on said first source/drain region;
an interconnection formed on said second contact plug;
a third contact plug formed on said second source/drain region; and
a capacitor formed on said third contact plug.

7. The semiconductor device according to claim 6,
wherein said first transistor comprises a plurality of first transistors,
said plurality of first transistors are arranged in a certain direction with said element isolation insulating film interposed therebetween, and
said gate structure is shared by said plurality of first transistors.

8. The semiconductor device according to claim 1,
wherein said second portion of said semiconductor substrate has a raised structure in cross-section, and
said gate structure is formed in contact with both of two opposite sides of said raised structure.

9. The semiconductor device according to claim 1, further comprising a second transistor formed in a second region of said semiconductor substrate,
wherein said second transistor comprises:
a gate insulating film formed on said main surface of said semiconductor substrate;
a gate electrode formed on said gate insulating film; and
a pair of source/drain regions formed in said main surface of said semiconductor substrate with a channel formation region, under said gate electrode, being interposed therebetween.

10. The semiconductor device according to claim 9,
wherein said first transistor has a gate insulating film in said gate structure, and
said gate insulating film of said first transistor and said gate insulating film of said second transistor have an equal film thickness.
